(19) United States
(12) Patent Application Publication
(10) Pub. No.: US 2018/0102456 A1
(43) Pub. Date: Apr. 12, 2018

(54) SEMICONDUCTOR OPTICAL DEVICE

(71) Applicant: KABUSHIKI KAISHA TOSHIBA, Minato-ku (JP)

(72) Inventors: Hirotaka Uemura, Kawasaki (JP); Mizunori Ezaki, Yokohama (JP); Kazuya Ohira, Tokyo (JP); Norio Iizuka, Kawasaki (JP); Haruhiko Yoshida, Funabashi (JP)

(73) Assignee: KABUSHIKI KAISHA TOSHIBA, Minato-ku (JP)

(21) Appl. No.: 15/692,483

(22) Filed: Aug. 31, 2017

(30) Foreign Application Priority Data
Oct. 11, 2016 (JP) 2016-199844

(51) Int. Cl. H01L 31/10; H01L 31/0203; H01L 31/0216; H01L 31/02; H01L 31/16

(52) U.S. Cl. CPC H01L 31/10; H01L 31/0203; H01L 31/165; H01L 31/02005; H01L 31/02165

(57) ABSTRACT

According to one embodiment, a semiconductor optical device including a substrate, a filter layer arranged on the substrate, and a semiconductor light receiving element arranged on the filter layer, wherein the filter layer includes a periodic structure through which a light of a desired wavelength range in incident light is transmitted, and which is constituted of different refractive index materials.

### CROSS-REFERENCE TO RELATED APPLICATIONS

This application is based upon and claims the benefit of priority from Japanese Patent Application No. 2016-199844, filed Oct. 11, 2016, the entire contents of which are incorporated herein by reference.

### FIELD

Embodiments described herein relate generally to a semiconductor optical device.

### BACKGROUND

Recently, in order to evaluate the physical properties of an object to be measured, various types of spectrometry such as the photoluminescence method, Raman spectrometric method, microscopic spectroscopy, and the like are widely utilized. In the spectrometry, information concerning the physical properties of an object to be measured such as the composition, bonding state or the like is obtained. At present, application of spectrometry to biometric measurement such as blood analysis (hemanalysis) and the like is investigated, and mass production of a small-sized spectrometric measuring devices having portability is required. In order to realize a small-sized spectrometric measuring device, a small-sized spectroscopic detector is needed.

In recent years, as a spectroscopic detector for visible light, an optical device formed by integrating a plurality of color filters different from each other in absorption characteristics on a semiconductor light receiving element is known. Although this optical device is downsized as compared with a conventional spectroscopic detector, there is a problem that a plurality of color filters are to be formed separately, and thus the manufacturing process becomes complicated.

### BRIEF DESCRIPTION OF THE DRAWINGS

FIG. 1 is a cross-sectional view illustrating a semiconductor optical device according to a first embodiment.

FIG. 2 is a plan view illustrating a filter layer of FIG. 1.

FIG. 3 is a view illustrating a reflection spectrum and transmission spectrum of the filter layer of FIG. 2.

FIG. 4 is a cross-sectional view illustrating a semiconductor optical device according to a second embodiment.

FIG. 5 is a view illustrating a reflection spectrum and transmission spectrum of the filter layer of FIG. 4.

FIG. 6 is a cross-sectional view illustrating a semiconductor optical device according to a third embodiment.

FIG. 7 is a cross-sectional view illustrating a semiconductor optical device according to a fourth embodiment.

FIG. 8 is a cross-sectional view illustrating a semiconductor optical device according to a fifth embodiment.

FIG. 9 is a cross-sectional view illustrating another example of the semiconductor optical device according to the fifth embodiment.

FIG. 10 is a cross-sectional view illustrating a semiconductor optical device according to a sixth embodiment.

FIG. 11 is a perspective view illustrating a semiconductor optical device according to a seventh embodiment.

### DETAILED DESCRIPTION

In general, according to one embodiment, there is provided a semiconductor optical device including: a substrate; a filter layer arranged on the substrate; and a semiconductor light receiving element arranged on the filter layer. The filter layer includes a periodic structure through which a light of a desired wavelength range in incident light is transmitted, and which is constituted of different refractive index materials.

Hereinafter, semiconductor optical devices according to the embodiments will be described in detail.

A semiconductor optical device according to an embodiment is provided with a substrate. On the substrate, a semiconductor light receiving element is arranged. A filter layer is provided between the substrate and the light receiving element. The filter layer has a periodic structure through which a desired light in the incident light is transmitted, and which is constituted of different refractive index materials, and light is made incident on the filter layer from the substrate side. The substrate can be made of various materials. It is desirable that the substrate be transparent with respect to the wavelength of the incident light, and for example, when the light incident on the semiconductor light receiving element is visible light, the substrate can be made of GaN or SiC. When the light incident on the semiconductor light receiving element is near-infrared light, the substrate can be made of Si, GaAs, or InP each having high optical transparency.

It is sufficient if the semiconductor light receiving element is a heretofore known conventional one and, for example, a light receiving element having a rectangular or circular planar shape, and having a pin-structure can be used. In the semiconductor light receiving element having the pin-structure, an electrode is connected to each of the p-type layer and the n-type layer. For example, when the p-type layer is formed of p-In0.53Ga0.47As, Ti/Pt/Au can be used as the p-type electrode, and when the p-type layer is formed of p-InP, Zn/Au can be used as the p-type electrode. For example, when the n-type layer is formed of n-GaAs, AuGe/Ni/Au can be used as the n-type electrode, and when the n-type layer is formed of n-InP, Ti/Pt/Au can be used as the n-type electrode.

The filter layer can be formed of, for example, a photonic crystal. The photonic crystal has a structure in which on a base material layer, a plurality of areas each having a refractive index different from the base material are periodically arranged in a one-dimensional direction or in a two-dimensional direction. More specifically, the photonic crystal has a structure in which a plurality of belt-like holes are periodically opened in a base material layer of, for example, a silicon oxide in one-dimensional direction or a plurality of circular or rectangular holes are periodically opened in the base material layer in a two-dimensional direction, and these holes are filled with amorphous silicon layers having a refractive index higher than the base material. Examples of the low refractive index material which is the base material include, for example, SiO₂, SiN, In₂O₃, AlN, Al₂O₃, AlOₓ (1<x<1.5), and the like. Examples of the high refractive index material include, for example, Si, GaN, SiC, TiO₂, Ta₂O₅, In₂O₃, AlN, SiN, GaAs, InP, and the like. Regarding such a filter layer, by changing the period of the periodic structure constituted of different refractive index materials, the wavelength of light transmitted through the filter layer can be selected.

In the semiconductor optical device according to the embodiment, the filter layer has various forms described below.

(1) A plurality of filter layers can be arranged between the substrate and the semiconductor light receiving element in the incident direction of light. In such a form, the plurality of filter layers transmits a light of a desired wavelength range in the incident light.

(2) A plurality of filter layers can be arranged on one surface of the substrate in an array form, and a semiconductor light receiving element can be provided on each of the filter layers. In such a form, each of the plurality of filter layers transmits therethrough a light of a desired wavelength range in the incident light, and their periodic structures each of which is constituted of different refractive index materials are different from each other.

(3) In a semiconductor optical device in which a semiconductor light-emitting element is further provided on the substrate, one or more filter layers can be arranged on the substrate, and a semiconductor light receiving element can be provided on each filter layer. In such a form, as the semiconductor light-emitting element, although not particularly limited, for example, a pin-structure semiconductor light-emitting element or a semiconductor laser can be used.

(4) In a semiconductor optical device in which a filter layer is arranged on the substrate, and a semiconductor light-emitting element is further provided on the filter layer, one or more filter layers can be arranged in an area or areas on the substrate different from the aforementioned filter layer, and a semiconductor light receiving element can be provided on each filter layer.

Next, the aforementioned embodiments will be described more specifically with reference to the drawings.

### First Embodiment

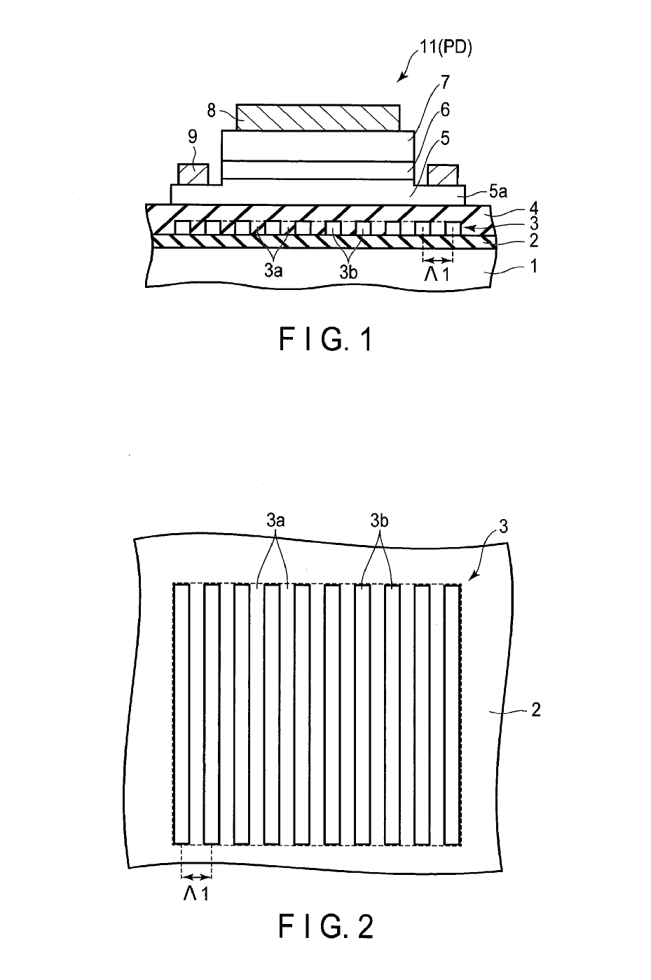

FIG. 1 is a cross-sectional view of a semiconductor optical device according to a first embodiment, and FIG. 2 is a plan view showing a filter layer of FIG. 1.

The semiconductor optical device is provided with a rectangular substrate 1 formed of, for example, silicon having high optical transparency. An insulating film 2 formed of, for example, a silicon oxide is provided on a principal surface of the substrate 1. A filter layer 3 transmitting a light of a desired wavelength range in the incident light is provided on a surface of the insulating film 2, and is formed of, for example, a photonic crystal having a periodic structure transmitting a light of a desired wavelength range in the incident light, and constituted of different refractive index materials. A planar shape of the filter layer 3 is rectangular. The photonic crystal has a structure including a base material layer 3a formed of, for example, a silicon oxide, and a plurality of belt-like layers 3b embedded in the base material layer 3a at regular intervals, and formed of a material having a refractive index higher than the base material (for example, amorphous silicon). Between certain belt-like layers 3b adjacent to each other, a period Λ1 of centerlines in the longitudinal direction is constant, and is, for example, 0.5 μm to 1.0 μm.

On the insulating film 2 including the filter layer 3, an insulating film 4 formed of a material identical to the insulating film 2 is provided with a surface thereof planarized. That is, the filter layer 3 is covered with the insulating film 2 and the insulating film 4. On a surface of a part of the insulating film 4 corresponding to the filter layer 3, a semiconductor light receiving element 11 is provided. The semiconductor light receiving element 11 is provided with a p-type layer 5, i-type layer 6, and n-type layers 7 which are each constituted of a III-V semiconductor such as InGaAs or the like, and these layers 5, 6, and 7 are stacked one on top of the other in the order mentioned. Planar shapes of the p-type layer 5, i-type layer 6, and n-type layer 7 are all rectangular. Part of the p-type layer 5 of the lowermost layer has an area larger than the i-type layer 6 and n-type layer 7 (both of which have shapes identical to each other) arranged on the p-type layer 5, and has a rectangularly annular brim part 5a outwardly and similarly jutting from the outer edge of the i-type layer 6 to be exposed. A rectangular n-type electrode 8 is provided on a surface of the n-type layer 7 of the uppermost layer. A rectangularly annular p-type electrode 9 is provided on a surface of the rectangularly annular brim part 5a of the p-type layer 5 of the lowermost layer.

The semiconductor optical device according to the first embodiment shown in FIG. 1 described above is provided with the filter layer 3 formed of, for example, a photonic crystal in which the refractive index periodically changes between the substrate 1 and the semiconductor light receiving element 11. When light is made incident on the filter layer 3 from the substrate 1 side, a light of a specific wavelength (or wavelength range) is transmitted through the filter layer 3, and a light of wavelength ranges other than the above specific wavelength (or wavelength range) are reflected. The light transmitted through the filter layer 3 is made incident on the semiconductor light receiving element 11 of the pin-structure, and here the light is subjected to photoelectric conversion, whereby a photoelectric current is generated. The generated photoelectric current can be taken out through the p-type electrode 9, and the n-type electrode 8 which are respectively connected to the p-type layer 5, and the n-type layer 7 of the semiconductor light receiving element 11. This photoelectric current is correlated with the intensity of the light of the specific wavelength (or wavelength range) transmitted through the filter layer 3. As a result, it is possible to measure the intensity of light of a specific wavelength (or wavelength range) incident on the semiconductor light receiving element 11 through the filter layer 3 by detecting a photoelectric current generated in the semiconductor light receiving element 11 by means of a pair of electrodes 8 and 9.

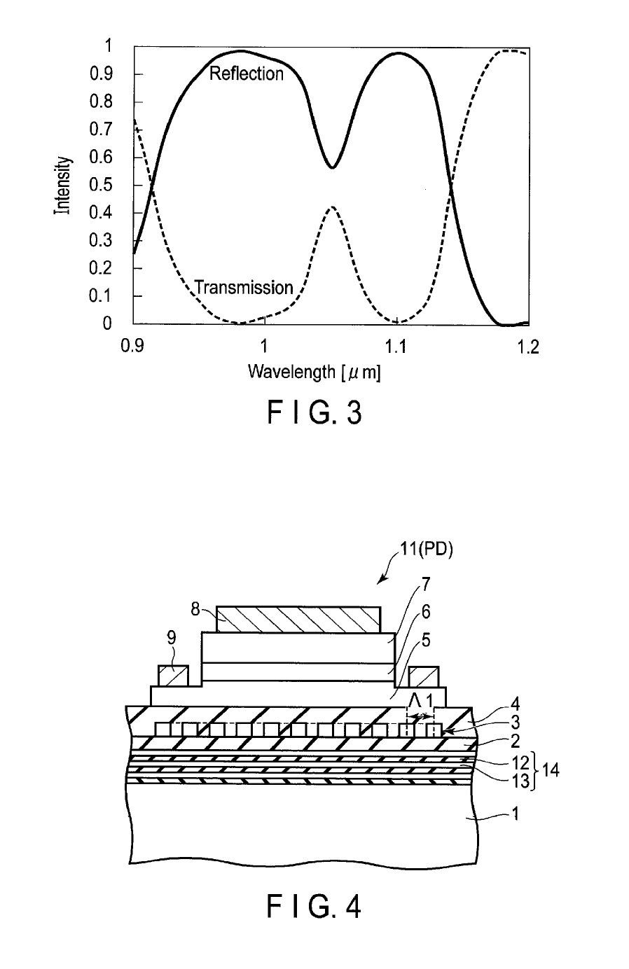

The filter layer 3 of the photonic crystal having a structure including the base material layer 3a formed of the silicon oxide, and the plurality of belt-like layers 3b embedded in the base material layer 3a at regular intervals, and formed of a material (for example, amorphous silicon) having a refractive index higher than the base material exhibits the wavelength selectivity illustrated in FIG. 3, when between belt-like layers 3b adjacent to each other, the period Λ1 of the centerlines in the longitudinal direction is constant, and is, for example, 0.56 μm, and the thickness of the belt-like layer 3b is 0.95 μm. FIG. 3 is a view illustrating a reflection spectrum and transmission spectrum of the filter layer of FIG. 2. As shown in FIG. 3, in the filter layer 3, at the bands of the wavelengths 0.97 μm and 1.10 μm, a reflectance of about 98% appears, and a reflectance of about 56% appears at the wavelength of 1.05 μm positioned between the above two wavelength ranges. Accordingly, the filter layer 3 functions as a reflective optical filter having an extinction ratio of about 22 at the band of a wavelength of 1.05 μm.

It should be noted that when the wavelength of the incident light is long, the period Λ1 of the filter layer 3 is made long and, on the other hand, when the wavelength of the incident light is short, the period Λ1 of the filter layer 3 is made short.

The filter layer 3 having such high wavelength selectivity and such a high extinction ratio is arranged between the substrate 1 and the semiconductor light receiving element 11, whereby when light is made incident on the filter layer 3 from the substrate 1 side, it is possible to transmit a light of a specific wavelength (or wavelength range) through the filter layer 3, reflect light of wavelength ranges other than the specific wavelength range, and measure the intensity of the light of the specific wavelength (or wavelength range) incident on the semiconductor light receiving element 11 through the filter layer 3 by means of the pair of electrodes 8 and 9.

Therefore, according to the semiconductor optical device of the first embodiment, it is possible to measure the intensity of a light of a specific wavelength (or wavelength range) in the incident light.

Further, when the semiconductor optical device according to the first embodiment is applied to a spectroscopic detector, the semiconductor optical device can be obtained by the already-existing semiconductor process, and hence it is possible to achieve simplification of manufacture and reduction in size as compared with the conventional spectroscopic detector.

### Second Embodiment

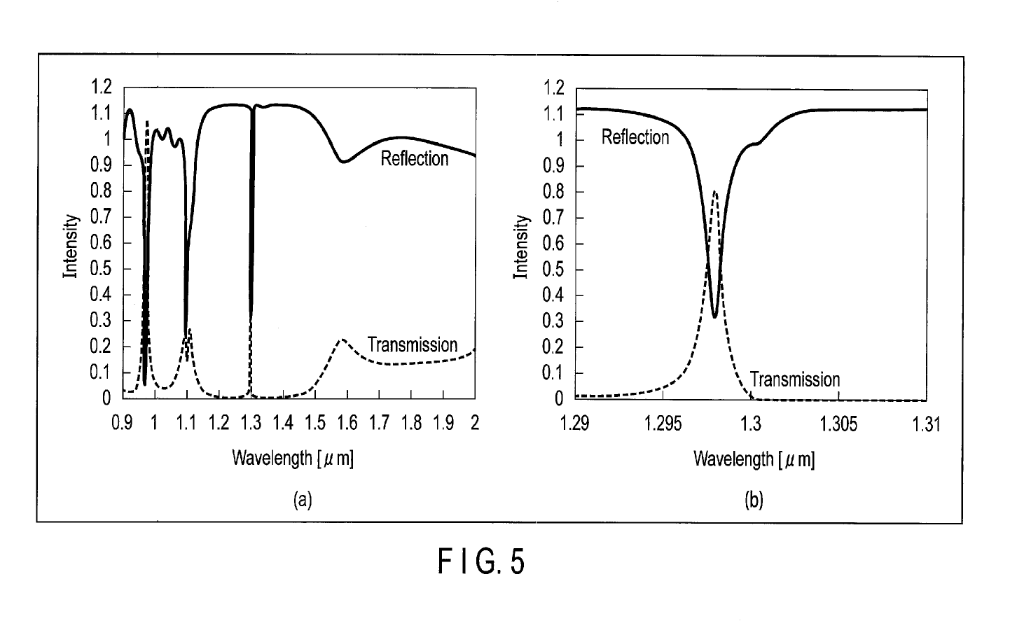

FIG. 4 is a cross-sectional view of a semiconductor optical device according to a second embodiment. It should be noted that in FIG. 4, members identical to FIG. 1 are denoted by reference symbols identical to FIG. 1, and a description of the members is omitted.

The semiconductor optical device according to the second embodiment is provided with a rectangular substrate 1 formed of, for example, silicon having high optical transparency. On a principal surface of the substrate 1, a laminated structure 14 in which, for example, a low refractive index layer 12 and a high refractive index layer 13 are alternately stacked one on top of the other is provided. In the laminated structure 14, for example, a silicon oxide layer 12 which is a low refractive index layer having three layers, and an amorphous silicon layer 13 which is a high refractive index layer having three layers are alternately stacked one on top of the other. On the laminated structure 14, an insulating film 2 is provided, and a filter layer 3 is provided on a surface of the insulating layer 2. The filter layer 3 is formed of a photonic crystal having a structure identical to that described in the first embodiment. It should be noted that between belt-like layers (not shown) of the filter layer 3 adjacent to each other, a period Λ1 of centerlines in the longitudinal direction is constant, and is 0.5 μm to 1.0 μm, for example, 0.6 μm. On the insulating film 2 including the filter layer 3, an insulating film 4 formed of a material identical to the insulating film 2 is provided with a surface thereof planarized. That is, the filter layer 3 is covered with the insulating film 2 and the insulating film 4. On a surface of the insulating film 4, a semiconductor light receiving element 11 having a structure identical to the first embodiment, and a pair of electrodes 8 and 9 are provided.

In the semiconductor optical device according to the second embodiment described above shown in FIG. 4, as in the case of the first embodiment, a light of a specific wavelength (or wavelength range) in the light incident from the substrate is transmitted, and a photoelectric current of the light of the wavelength (or wavelength range) is detected by the pair of electrodes 8 and 9, whereby it is possible to measure the intensity of the light of the specific wavelength (or wavelength range) incident on the semiconductor light receiving element 11.

Further, in the semiconductor optical device according to the second embodiment, the light incident on the substrate 1 side is transmitted through the laminated structure 14 and the filter layer 3, and is thereafter made incident on the semiconductor light receiving element 11. Both the laminated structure 14 and the filter layer 3 are high reflectance layers, and hence exhibit transmission characteristics equivalent to the Fabry-Perot resonator or the diffraction grating with phase shift with respect to the light transmitted through the laminated structure 14 and the filter layer 3. As a result, the light of the wavelength transmitted through the structure 14 and the layer 3 becomes the light of a narrower band as compared with the filter layer of a single layer illustrated in FIG. 1. That is, the laminated structure 14 and the filter layer 3 are arranged between the substrate 1 and the semiconductor light receiving element 11, whereby it is possible to design an optical filter having high wavelength selectivity of the transmitted light.

That is, when the laminated structure 14 formed of, for example, an alternately-laminated film periodically changing in refractive index, and the filter layer 3 formed of a photonic crystal are provided between the substrate 1 and the semiconductor light receiving element 11, and the thickness of the amorphous silicon layer 13 of the laminated structure 14 is 0.092 μm, and the thickness of the silicon oxide layer 12 thereof is 0.225 μm, and the period Λ1 of the filter layer 3 is 0.5 to 0.6 μm, for example, 0.56 μm, a transmission spectrum and a reflection spectrum illustrated in each of (a) and (b) of FIG. 5 appear. It should be noted that (b) of FIG. 5 is a view in which a part in the vicinity of the wavelength range (1.29 to 1.31 μm) of (a) of FIG. 5 is enlarged. As shown in (a) and (b) of FIG. 5, when the filter layer 3 and the laminated structure 14 are arranged in the incident direction, transmission characteristics of a narrow band in which a transmittance band with a width of about 1 nm appears in the high reflectance wavelength band of the wavelength range (wavelength range of 1.2 μm to 1.4 μm) of 200 nm are exhibited. Further, the filter layer 3 and the laminated structure 14 function as an optical filter of an extinction ratio of about 60 owing to the relationship between the transmittance and the reflectance.

It should be noted that in FIG. 4, as the laminated structure 14, an example in which the silicon oxide layer 12 and the amorphous silicon layer 13 are alternately stacked one on top of the other is illustrated, the laminated structure is not limited to this. The low refractive index semiconductor layer 12 and the high refractive index layer 13 may be formed of a semiconductor material such as a p-type GaAs layer, p-type AlGaAs layer, and the like.

### Third Embodiment

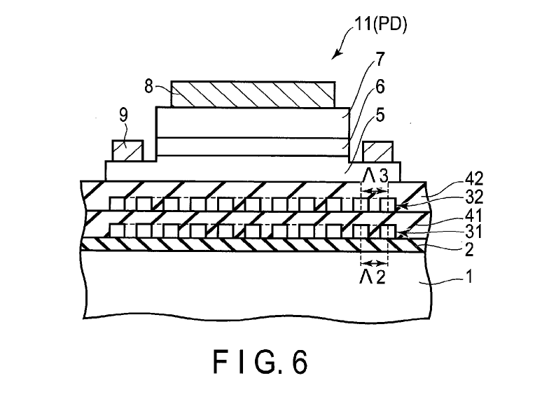

FIG. 6 is a cross-sectional view of a semiconductor optical device according to a third embodiment. It should be noted that in FIG. 6, members identical to FIG. 1 and FIG. 4 are denoted by reference symbols identical to FIG. 1 and FIG. 4, and a description of the members is omitted.

The semiconductor optical device according to the third embodiment is provided with a rectangular substrate 1 formed of, for example, silicon having high optical transparency. On a principal surface of the substrate 1, an insulating film 2 is provided. On a surface of the insulating film 2, a first filter layer 31 is provided, and is formed of a photonic crystal having a structure identical to that described in the first embodiment. It should be noted that between belt-like layers (not shown) of the first filter layer 31 adjacent to each other, a period Λ2 of centerlines in the longitudinal direction is constant, and is 0.5 μm to 1.0 μm, for example, 0.6 μm. On the insulating film 2 including the filter layer 31, an insulating film 41 formed of a material identical to the insulating film 2 is provided with a surface thereof planarized. That is, the first filter layer 31 is covered with the insulating film 2 and the insulating film 41. A second filter layer 32 is provided on a surface of the insulating film 41, and is formed of a photonic crystal having a structure identical to that described in the first embodiment. It should be noted that it is desirable that between belt-like layers (not shown) of the second filter layer 32 adjacent to each other, a period Λ3 of centerlines in the longitudinal direction be constant, and be a value identical to, for example, the period Λ2 of the first filter layer 31. It should be noted that the period Λ2 of first filter layer 31, and the period Λ3 of the second filter layer 32 may be values different from each other. On the insulating film 41 including the second filter layer 32, an insulating film 42 formed of a material identical to the insulating film 2 is provided with a surface thereof planarized. That is, the second filter layer 32 is covered with the insulating film 41 and the insulating film 42. On a surface of the insulating film 42, a semiconductor light receiving element 11 and a pair of electrodes 8 and 9 are provided, which have the structure identical to the first embodiment.

In the semiconductor optical device according to the third embodiment described above illustrated in FIG. 6, as in the case of the first embodiment, a light of a specific wavelength (or wavelength range) in the light incident from the substrate 1 side is transmitted, and a photoelectric current of a light of the wavelength (or wavelength range) is detected by the pair of electrodes 8 and 9, whereby it is possible to measure the intensity of the light of the specific wavelength (or wavelength range) incident on the semiconductor light receiving element 11.

Further, in the semiconductor optical device according to the third embodiment, the light incident on the substrate 1 side is transmitted through the two layers of the filter layers 31 and 32 in the incident direction, and is thereafter made incident on the semiconductor light receiving element 11.

The filter lays 31 and 32 are high reflectance layers, and hence exhibit transmission characteristics equivalent to the Fabry-Perot resonator or the diffraction grating with phase shift with respect to the light transmitted through the two filter layers as in the case of the second embodiment. As a result, the light of the wavelength transmitted through the two filter layers becomes the light of a narrower band as compared with the filter layer of a single layer illustrated in FIG. 1. That is, a plurality of filter layers are arranged between the substrate 1 and the semiconductor light receiving element 11, whereby it is possible to design an optical filter having high wavelength selectivity of the transmitted light.

### Fourth Embodiment

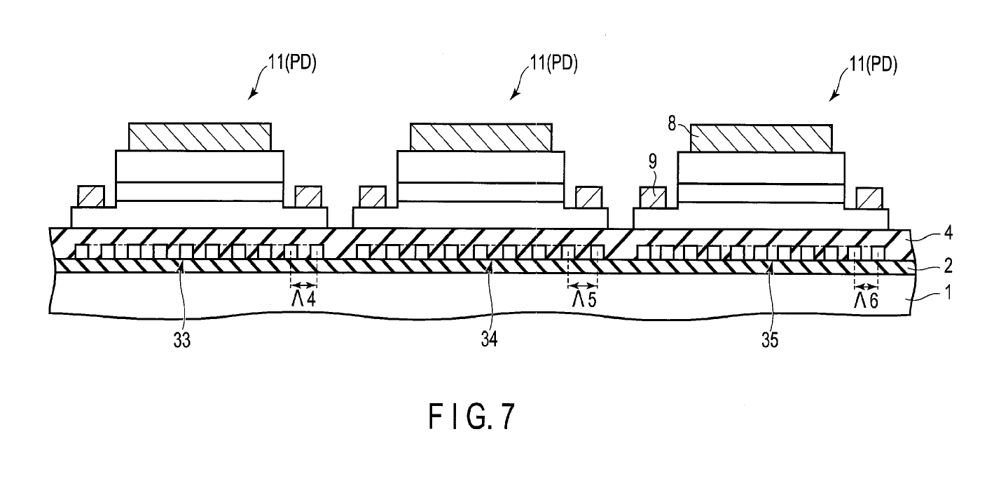

FIG. 7 is a cross-sectional view of a semiconductor optical device according to a fourth embodiment. It should be noted that in FIG. 7, members identical to FIG. 1 are denoted by reference symbols identical to FIG. 1, and a description of the members is omitted.

The semiconductor optical device according to the fourth embodiment is provided with a rectangular substrate 1 formed of, for example, silicon having high optical transparency. An insulating film 2 formed of, for example, a silicon oxide is provided on a principal surface of the substrate 1. A first filter layer 33, second filter layer 34, and third filter layer 35 are respectively provided on a surface of the insulating film 2, and each of them is formed of a photonic crystal having a structure identical to that described in the first embodiment. It should be noted that between belt-like layers (not shown) of the first filter layer 33 adjacent to each other, a period Λ4 of centerlines in the longitudinal direction is constant, and is 0.5 μm to 1.0 μm, for example, 0.55 μm. The period Λ5 of the second filter layer 34 is constant, and is 0.5 μm to 1.0 μm, for example, 0.60 μm. The period Λ6 of the third filter layer 35 is constant, and is 0.5 μm to 1.0 μm, for example, 0.50 μm. On the insulating film 2 including the first to third filter layers 33, 34, and 35, an insulating film 4 formed of a material identical to the insulating film 2 is provided with a surface thereof planarized. That is, the first to third filter layers 33, 34, and 35 are covered with the insulating film 2 and the insulating film 4.

On a surface of the insulating film 4, groups each of which is constituted of a semiconductor light receiving element 11 and a pair of electrodes 8 and 9 having a structure identical to the first embodiment are provided in such a manner that the groups respectively correspond to the first to third filter layers 33, 34, and 35.

In the semiconductor optical device according to the fourth embodiment described above shown in FIG. 7, as in the case of the first embodiment, each of light of specific wavelengths (or wavelength ranges) in the light incident from the substrate 1 side is transmitted through corresponding one of the first to third filter layers 33, 34, and 35. Then, a photoelectric current of each of the light of the specific wavelengths (or wavelength ranges) is detected by the corresponding pair of electrodes 8 and 9. Thereby it is possible to separately measure the intensity of the light of each specific wavelength (or wavelength range) incident on each semiconductor light receiving element 11.

Further, when the semiconductor optical device according to the fourth embodiment is applied to a spectroscopic detector, the first to third filter layers 33, 34, and 35 and the semiconductor light receiving elements 11 corresponding to these filter layers can be obtained by an already-existing semiconductor process, and by the same process, and hence it is possible to achieve simplification of manufacture and reduction in size as compared with the conventional spectroscopic detector.

It should be noted that in the fourth embodiment, each filter layer arranged on the substrate may be arranged in the incident direction in two layers or in three or more layers as in the case of the third embodiment. Further, as in the case of the second embodiment, between the insulating film 2 and the substrate 1, a laminated structure formed by alternately stacking materials having different refractive indexes one on top of the other may be arranged together with the filter layer.

### Fifth Embodiment

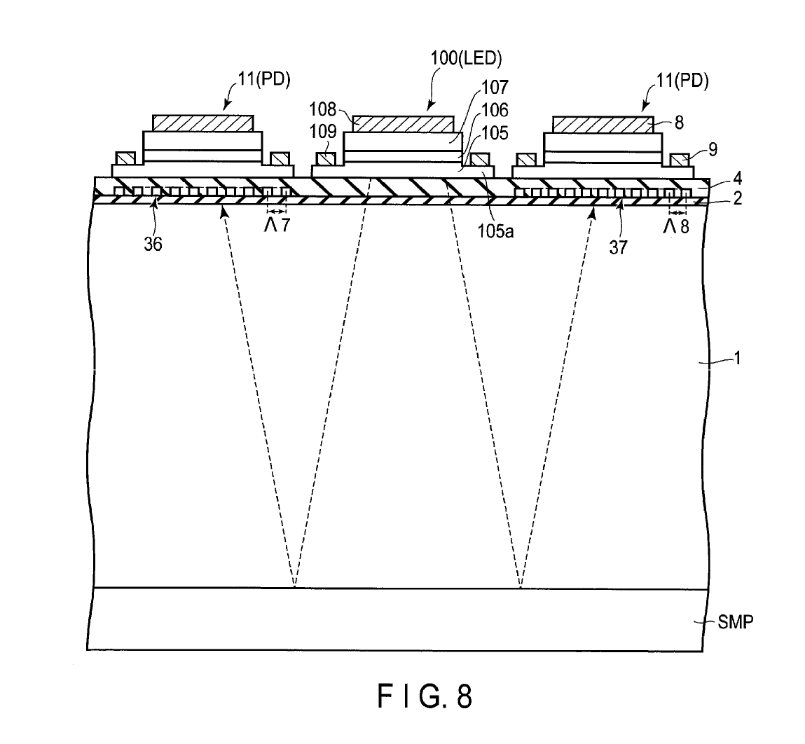

FIG. 8 is a cross-sectional view of a semiconductor optical device according to a fifth embodiment. It should be noted that in FIG. 8, members identical to FIG. 1 are denoted by reference symbols identical to FIG. 1, and a description of the members is omitted.

The semiconductor optical device according to the fifth embodiment is provided with a rectangular substrate 1 formed of, for example, silicon having high optical transparency. An insulating film 2 formed of, for example, a silicon oxide is provided on a principal surface of the substrate 1. A first filter layer 36 and second filter layer 37 are respectively provided on a surface of the insulating film 2 with a desired space held between them, and each of them is formed of a photonic crystal having a structure identical to that described in the first embodiment. It should be noted that between belt-like layers (not shown) of the first filter layer 36 adjacent to each other, a period Λ7 of centerlines in the longitudinal direction is constant, and is, for example, 0.6 μm. A period Λ8 of the second filter layer 37 is constant, and is, for example, 0.5 μm. On a surface of the insulating film 2 including the first and second filter layers 36 and 37, an insulating film 4 formed of a material identical to the insulating film 2 is provided with a surface thereof planarized. That is, the first and second filter layers 36 and 37 are covered with the insulating film 2 and the insulating film 4.

On a surface of the insulating film 4, groups each of which is constituted of a semiconductor light receiving element 11 and a pair of electrodes 8 and 9 having a structure identical to the first embodiment are provided in such a manner that the groups respectively correspond to the first and second filter layers 36 and 37.

On the surface of the insulating film 4 at a position between the first and second filter layers 36 and 37, a semiconductor light-emitting element 100 is provided. The semiconductor light-emitting element 100 is provided with a p-type layer 105, i-type layer 106, and n-type layer 107 which are each constituted of a III-V semiconductor such as InGaAs or the like, and these layer 105, 106, and 107 are stacked one on top of the other in the order mentioned. The planar shape of each of the p-type layer 105, i-type layer 106, and n-type layer 107 is rectangular. The p-type layer 105 of the lowermost layer has an area larger than the i-type layer 106 and n-type layer 107 (which are identical to each other in dimension) on and above the layer 105, and has a rectangularly annular brim part 105a outwardly and similarly jutting from the outer edge of the i-type layer 106 to be exposed. A rectangular n-type electrode 108 is provided on a surface of the n-type layer 107 of the uppermost layer. A rectangularly annular p-type electrode 109 is provided on a surface of the rectangularly annular brim part 105a of the p-type layer 105 of the lowermost layer.

It should be noted that the semiconductor light receiving element 11 on the left side, semiconductor light receiving element 11 on the right side, and semiconductor light-emitting element 100 are separated from each other with a distance of, for example, 100 μm held between them.

In the semiconductor optical device according to the fifth embodiment described above, an object to be measured SMP is arranged on an underside of the substrate 1 in contact with a position directly under the semiconductor light-emitting element 100. When a voltage is applied to the n-type layer 107 and the p-type layer 105 of the semiconductor light-emitting element 100 from the n-type electrode 108 and the p-type electrode 109, photoelectric conversion is carried out in the i-type layer 106, and light is generated. The light generated in the semiconductor light-emitting element 100 is reflected from the n-type electrode 108 serving also as a reflection film, and is downwardly emitted from the substrate 1. The emitted light is reflected from or is diffused by the surface of the object to be measured SMP arranged in contact with the underside of the substrate 1. The light reflected from or diffused by the object to be measured SMP is incident on each of the first filter layer 36 and the second filter layer 37 arranged between the substrate 1 and the two semiconductor light receiving elements 11 through the substrate 1. The first and second filter layers 36 and 37 transmit, in the manner identical to that described in the first embodiment, a light of specific wavelengths (or wavelength ranges) in the light reflected from or diffused by the object to be measured SMP, and reflect a light of other wavelengths. Then, a photoelectric current of each of the transmitted a light of the wavelengths (or wavelength range) generated in each of the semiconductor light receiving elements 11 corresponding to the first and second filter layers 36 and 37 is detected by each corresponding pair of electrodes 8 and 9, whereby it is possible to separately measure the intensity of the light of each specific wavelength (or wavelength range) incident on each semiconductor light receiving element 11.

Therefore, according to the semiconductor optical device of the fifth embodiment, light reflected from or diffused by the surface of the object to be measured SMP can be measured by spectrometry, and hence the physical properties of the object to be measured SMP such as a minute surface state or the like can be obtained. Accordingly, the semiconductor optical device according to the fifth embodiment can be utilized as a small-sized one-chip spectrometric measuring device.

In the semiconductor optical device according to the fifth embodiment, the semiconductor layer in the semiconductor light-emitting element 100 and the semiconductor layer of the semiconductor light receiving element 11 have an identical layer structure, and are formed of an identical semiconductor material. Although the base materials and the dielectric materials constituting the filter layers 36 and 37 are also identical to each other, it is possible, by designing of the etching mask, to easily change the periods Λ7 and Λ8 with which the refractive indexes change, and arrange filter layers corresponding to more numerous wavelengths in parallel. Accordingly, it is possible, even when the number of wavelength ranges to be measured is increased, to integrate a large number of semiconductor light receiving elements each provided with filter layers on one substrate without increasing the number of manufacturing processes.

Further, when the semiconductor optical device according to the fifth embodiment is applied to a spectroscopic detector, the semiconductor optical device can be obtained by an already-existing semiconductor process, and hence it is possible to achieve simplification of manufacture and reduction in size as compared with the conventional spectroscopic detector requiring implementation and alignment of optical components. Further, whereas in the conventional spectroscopic detector, the accuracy of the detection wavelength is deteriorated due to misalignment in the optical system caused by vibration, in the fifth embodiment, there is no need for alignment of the optical system, and hence it becomes possible to use the spectroscopic detector even at a place subject to strong vibration.

It should be noted that although in the fifth embodiment, an example in which one semiconductor light-emitting element, and two semiconductor light receiving elements are provided is illustrated, the example is not limited to this. The number of semiconductor light receiving elements to be integrated on one substrate is appropriately changed according to the number of wavelengths which are made the object of measurement, and the use of the semiconductor optical device. Further, although in the fifth embodiment, an example in which the periods of a plurality of filter layers with which the refractive indexes change are different from each other is shown, the example is not limited to this, and the example may include filter layers each having an identical period. Furthermore, regarding the filter layer used in the fifth embodiment, as in the case of the filter layer shown in the second embodiment, between the filter layer and the substrate, a laminated structure formed by alternately stacking materials having different refractive indexes one on top of the other may be arranged together with the filter layer. Furthermore, regarding the filter layer used in the fifth embodiment, as in the case of the filter layers shown in the third embodiment, two or more filter layers may be arranged in the incident direction of the light.

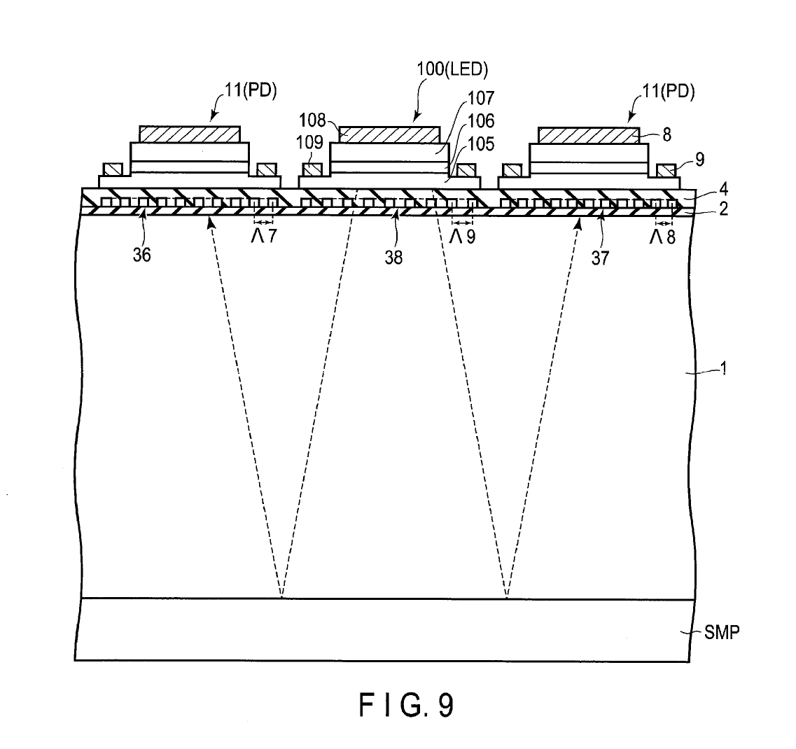

In another example of the semiconductor optical device according to the fifth embodiment, as illustrated in FIG. 9, a configuration in which a filter layer 38 is further provided between the semiconductor light-emitting element 100 and the substrate 1 may be employed. The filter layer 38 is provided on the surface of the insulating film 2 with desired spaces held on both sides thereof, and is formed of a photonic crystal having a structure identical to that described in the first embodiment. According to this configuration, it is possible to transmit only a light of a narrow band in the light emitted from the semiconductor light-emitting element 100, and irradiate the object to be measured SMP with the transmitted light. In this example too, as in the case of the above-mentioned example, it is possible to measure light reflected from or diffused by the surface of the object to be measured SMP.

At this time, by irradiating the object to be measured SMP with light of the narrow band, whereby it is possible to realize a configuration in which a substance on the surface of the object to be measured is made to emit fluorescent light or phosphorescent light by being excited. As a result, photoluminescence measurement of measuring a fluorescence or phosphorescence emission spectrum by means of the semiconductor light receiving element 11 is enabled. In the conventional photoluminescence measurement, an optical device having a high extinction ratio such as a notch filter or a grating is required in order that the excitation light may not be made incident on the semiconductor light receiving element. Conversely, in another example of the fifth embodiment, when the emission spectrum of the light emitted by exciting the substance on the surface of the object to be measured SMP is transmitted through the first and second filter layers 36 and 37, the excitation light is reflected from the first and second filter layers 36 and 37 exhibiting a high reflectance as described in the first embodiment. Therefore, it is possible to prevent the excitation light from being made incident on the semiconductor light receiving element 11 without separately providing an optical device having a high extinction ratio unlike in the conventional measurement.

### Sixth Embodiment

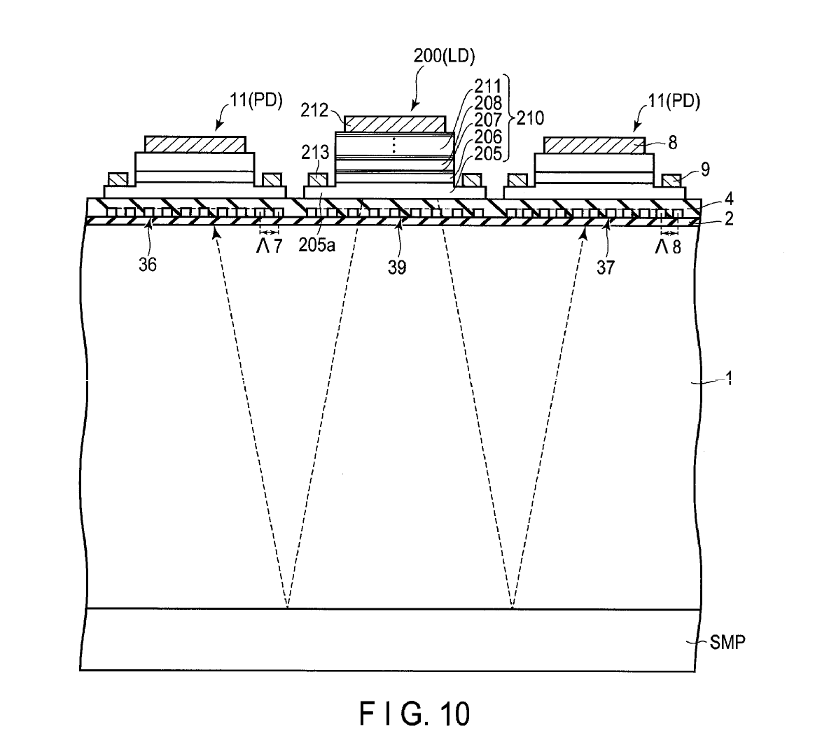

FIG. 10 is a cross-sectional view of a semiconductor optical device according to a sixth embodiment. It should be noted that in FIG. 10, members identical to FIG. 8 are denoted by reference symbols identical to FIG. 8, and a description of the members is omitted.

The semiconductor optical device according to the sixth embodiment is provided with a rectangular substrate 1 formed of, for example, silicon having high optical transparency. An insulating film 2 formed of, for example, a silicon oxide is provided on a principal surface of the substrate 1. A first filter layer 36 and second filter layer 37 are respectively provided on a surface of the insulating film 2 with a desired space held between them, and are each formed of a photonic crystal having a structure identical to that described in the first embodiment.

A reflecting layer 39 formed of, for example, a photonic crystal having a periodic structure constituted of different refractive index materials is provided on a part of a surface of the insulating film 2 positioned between the first and second filter layers 36 and 37. On the surface of the insulating film 2 including the first and second filter layers 36 and 37, and the reflecting layer 39, an insulating film 4 formed of a material identical to the insulating film 2 is provided with a surface thereof planarized. That is, the first and second filter layers 36 and 37, and the reflecting layer 39 are covered with the insulating film 2 and the insulating film 4. The reflecting layer 39 functions as a first reflecting layer serving as a reflecting mirror constituting an optical resonator of a semiconductor laser 200.

On a surface of the insulating film 4 including the reflecting layer 39, a semiconductor laser 200 (LD) which is a semiconductor light-emitting element is provided. The semiconductor laser 200 is provided with a semiconductor layer 210 formed by stacking an n-type contact layer 205, n-type spacer layer 206, active layer 207, and p-type spacer layer 208 which are formed of compound semiconductors one on top of the other in the order mentioned.

On a surface of the p-type spacer layer 208 positioned at the uppermost layer of the semiconductor layer 210, a multi-layer reflection film 211 is provided as a reflecting layer. The multi-layer reflection film 211 is a distributed bragg reflector (DBR) miller formed by alternately stacking high refractive index semiconductor layers and low refractive index semiconductor layers one on top of the other. The multi-layer reflection film 211 functions, for example, as a second reflecting layer. The high refractive index semiconductor and low refractive index semiconductor layer are, for example, a p-type GaAs layer, and p-type AlGaAs layer. The part of the semiconductor layer 210 from the superficial layer of a predetermined depth of the n-type contact layer 205 positioned at the lowermost layer to the p-type spacer layer 208 of the uppermost layer, and the multi-layer reflection film 211 constitute a rectangular laminated body structure. A part of the n-type contact layer 205 having a rectangular shape positioned of the lowermost layer of the laminated body structure has an area larger than the n-type spacer layer 206, active layer 207, and p-type spacer layer 208 which are positioned higher than the n-type contact layer 205. The n-type contact layer 205 has a rectangularly annular brim part 205a outwardly and similarly jutting from the outer edge of the n-type spacer layer 206 to be exposed. A rectangular p-type electrode 212 is provided on a surface of the multi-layer reflection film 211 of the uppermost layer. A rectangularly annular n-type electrode 213 is provided on a surface of the rectangularly annular brim part 205a of the n-type contact layer 205 of the lowermost layer.

On a surface of the insulating film 4 including the first filter layer 36 and the second filter layer 37, for example, semiconductor light receiving elements 11 are each formed.

In the semiconductor optical device according to the sixth embodiment described above illustrated in FIG. 10, an object to be measured SMP is arranged on the underside of the substrate 1 in contact with a position directly under the semiconductor light-emitting element 100. When a voltage is applied to the multi-layer reflection film 211 and the semiconductor layer 210 of the semiconductor laser 200 from the n-type electrode 213 and the p-type electrode 212, photoelectric conversion is carried out in the active layer 207, and light is generated. The light generated in the semiconductor light-emitting element 200 is amplified by an optical resonator formed between the reflecting layer 39 formed of a photonic crystal and the multi-layer reflection film 211 while being subjected to resonance, and monochromatic light is downwardly emitted in a direction perpendicular to the substrate 1 through the reflecting layer 39. The emitted monochromatic light excites a substance on the surface of the object to be measured SMP arranged on the underside of the substrate 1, and fluorescent light or phosphorescent light is emitted. The light emitted from the object to be measured SMP is made incident on the first filter layer 36 and the second filter layer 37 arranged between the substrate 1 and the two semiconductor light receiving elements 11 through the substrate 1. The first and second filter layers 36 and 37 transmit light of specific wavelengths (or wavelength ranges) in the light reflected from or diffused by the object to be measured SMP, and reflect light of other wavelengths as described in the first embodiment. Then, a photoelectric current of each of the transmitted light of the wavelengths (or wavelength ranges) generated in each of the semiconductor light receiving elements 11 corresponding to the first and second filter layers 36 and 37 is detected by a corresponding pair of electrodes 8 and 9, whereby it is possible to measure the intensity of each of the light of the specific wavelengths (or wavelength ranges) incident on the semiconductor light receiving elements 11 as a fluorescence or phosphorescence emission spectrum.

Accordingly, the semiconductor optical device according to the sixth embodiment can carry out photoluminescence spectrometry.

Further, in the conventional photoluminescence measurement, an optical device having a high extinction ratio such as a notch filter or a grating is required in order that the excitation light may not be made incident on the semiconductor light receiving element.

Conversely, in the sixth embodiment, when the fluorescent light or phosphorescent light emitted by exciting the object to be measured SMP is transmitted through the first and second filter layers 36 and 37, the excitation light is reflected from the first and second filter layers 36 and 37 each exhibiting a high reflectance as described in the first embodiment. Therefore, it is possible to prevent the excitation light from being made incident on the semiconductor light receiving element 11 without separately providing an optical device having a high extinction ratio unlike in the conventional measurement.

It should be noted that according to the semiconductor optical device of the sixth embodiment, by employing a configuration in which wavelength resolution and a high extinction ratio can be obtained by the filter layer as in the second and third embodiments, it is possible to carry out spectrometry such as Raman scattered light measurement. Further, in the semiconductor optical device according to the sixth embodiment too, spectrometry of reflected light or diffused light of the object to be measured described in the fifth embodiment can be carried out.

It should be noted that although in the sixth embodiment, an example in which one semiconductor light-emitting element and two semiconductor light receiving elements are provided is shown, the example is not limited to this. The number of semiconductor light receiving elements integrated on one substrate is appropriately changed according to the number of wavelengths which is the object to be measured and the use of the semiconductor optical device. Further, although in the sixth embodiment, an example in which the periods of the plurality of filter layers with which the refractive indexes change are different from each other is shown, the example is not limited to this, and the example may include filter layers each having an identical period. Furthermore, although a description has been given by taking the distributed bragg reflector (DBR) mirror as an example of the second reflecting mirror in the semiconductor laser of the sixth embodiment, a structure identical to the reflecting layer 39 may be used as the second reflecting layer.

### Seventh Embodiment

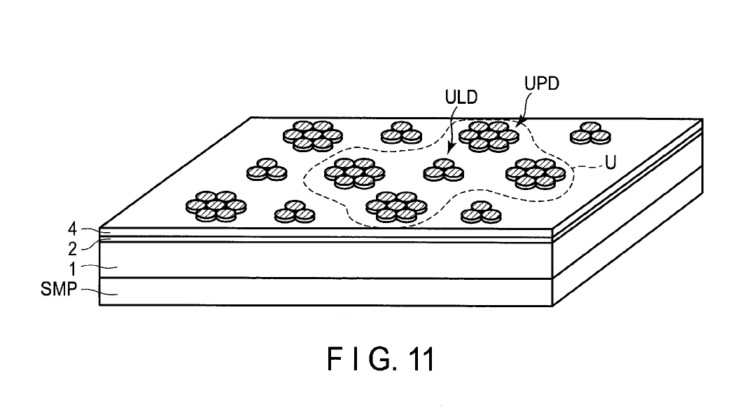

FIG. 11 is a perspective view showing a semiconductor optical device according to a seventh embodiment.

The semiconductor optical device according to the seventh embodiment is provided with a rectangular substrate 1 formed of, for example, silicon having high optical transparency. An insulating film 2 formed of, for example, a silicon oxide is provided on a principal surface of the substrate 1. An insulating film 4 is provided on a surface of the insulating film 2. A filter layer (not shown) is provided between the insulating films 2 and 4. The filter layer is formed of a photonic crystal having a structure identical to that described in the first embodiment.

On a surface of the insulating film 4, a light-emitting unit ULD constituted of a plurality of semiconductor light-emitting elements (for example, light-emitting diodes or semiconductor lasers) and light receiving units UPDs each of which is constituted of a plurality of semiconductor light receiving elements, and which surround the unit ULD on four sides are arranged.

Further, the light-emitting units ULDs each of which is constituted of a plurality of semiconductor light-emitting elements, and which surround the light receiving nit UPD on four sides are arranged. A unit including a light-emitting unit ULD and four light receiving units UPDs surrounding the light-emitting unit ULD is made one measurement unit U. It should be noted that the light receiving unit UPD constituted of the plurality of semiconductor light receiving elements is provided on a surface of the insulating film 4 in such a manner that the unit UPD corresponds to the filter layer.

According to the semiconductor optical device of the seventh embodiment illustrated in FIG. 11, it is possible to carry out spectrometry of a surface of an object to be measured as in the fifth and sixth embodiments. The measurement units U are scanned in sequence in such a manner that after emission in one light-emitting unit ULD is finished, light of another light-emitting unit ULD is emitted, whereby it is possible to examine physical properties corresponding to a position on the surface of the object to be measured SMP. In the light receiving unit UPD, a plurality of semiconductor light receiving elements capable of detecting light of different wavelengths are integrated, and hence more accurate spectrometry can be carried out.

It should be noted that the small-sized spectrometric measuring device constituted of the semiconductor optical device according to the fifth, sixth, and seventh embodiments can also be applied to biometric measurement represented by, for example, near-infrared spectroscopy. More specifically, the skin of a human body is made an object to be measured SMP, the semiconductor optical device is placed on the skin, and measurement is carried out in the manner identical to the aforementioned example. When the semiconductor optical device according to the seventh embodiment is taken as an example, light output from the light-emitting unit ULD is, after arriving at the object to be measured SMP, diffused into the object to be measured SMP, and part of the diffused light is released at the position of the light receiving unit UPD. In the light receiving unit UPD, each photoelectric current at each semiconductor light receiving element is detected as in the semiconductor optical devices according to the fifth and sixth embodiments, whereby it is possible to carry out biometric measurement such as blood analysis (hemanalysis) of oxygen or a blood glucose value in blood, brain wave measurement, and the like. Examples of application described in, for example, Jpn. Pat. Appln. KOKAI Publication No. 2001-87250, Jpn. Pat. Appln. KOKAI Publication No. 2013-188308, Jpn. Pat. Appln. KOKAI Publication No. 2012-95803, and Jpn. Pat. Appln. KOKAI Publication No. 2014-124454 are conceivable.

It should be noted that a wavelength of light emitted from or received by the semiconductor optical device is, for example, that of visible light or near-infrared light. The material of each member, period of the filter layer, and the like are appropriately selected according to the use. That is, the numerical value range of the aforementioned periods Λ1 to Λ8 is only an example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor optical device comprising:
a substrate;
a filter layer arranged on the substrate; and
a semiconductor light receiving element arranged on the filter layer, wherein
the filter layer includes a periodic structure through which a light of a desired wavelength range in incident light is transmitted, and which is constituted of different refractive index materials.

2. The semiconductor optical device of claim 1, further comprising a laminated structure arranged between the substrate and the filter layer, the laminated structure comprising at least two layers different from each other in refractive index, each of the at least two layers being alternately stacked one on top of the other.

3. The semiconductor optical device of claim 1, wherein a plurality of filter layers are arranged on the substrate, and a semiconductor light receiving element is arranged on each of the filter layers.

4. The semiconductor optical device of claim 3, wherein each of the filter layers includes a periodic structure, periods of the periodic structures being different from each other.

5. The semiconductor optical device of claim 1, wherein the filter layer includes the periodic structure constituted of a silicon oxide of a low refractive index, and amorphous silicon of a high refractive index.

6. The semiconductor optical device of claim 1, wherein the filter layer is constituted of a photonic crystal.

7. The semiconductor optical device of claim 1, wherein the filter layer is constituted of a base material layer of a low refractive index, and a plurality of belt-like layers of a high refractive index which are provided in the base material layer with a desired period.

8. The semiconductor optical device of claim 1, wherein the semiconductor light receiving element comprises a pin-structure formed of a III-V semiconductor, and a pair of electrodes configured to apply a voltage to the pin-structure.

9. The semiconductor optical device of claim 1, further comprising a semiconductor light-emitting element arranged at a position different from the semiconductor light receiving element on the substrate.

10. The semiconductor optical device of claim 9, wherein the semiconductor light-emitting element comprises a semiconductor layer including an active layer arranged on the substrate, and a pair of electrodes configured to apply a voltage to the active layer, further comprising a first reflecting layer which is provided between the substrate and the semiconductor layer, and a second reflecting layer which is provided on the semiconductor layer.

11. The semiconductor optical device of claim 10, wherein the semiconductor layer is formed of a III-V semiconductor.

12. The semiconductor optical device of claim 10, wherein the first reflecting layer is constituted of a photonic crystal.

13. The semiconductor optical device of claim 10, wherein the second reflecting layer is a multi-layer reflection film.

14. The semiconductor optical device of claim 13, wherein the multi-layer reflection film comprises a laminated body formed by alternately stacking two layers different from each other in refractive index one on top of the other.

15. The semiconductor optical device of claim 10, wherein the semiconductor light-emitting element is a semiconductor laser.
